(19) United States
(12) Patent Application Publication
(10) Pub. No.: US 2021/0230741 A1
(43) Pub. Date: Jul. 29, 2021

(54) Film Forming Method

(71) Applicant: ULVAC, INC., Kanagawa (JP)

(72) Inventors: Shuji Kodaira, Kanagawa (JP); Teppei Takahashi, Kanagawa (JP); Takahiro Tobiishi, Kanagawa (JP); Norifumi Yamamura, Kanagawa (JP); Hiroaki Katagiri, Kanagawa (JP); Junya Kubo, Kanagawa (JP); Masaaki Suzuki, Kanagawa (JP)

(73) Assignee: ULVAC, INC., Kanagawa (JP)

(21) Appl. No.: 16/966,661

(22) PCT Filed: Dec. 11, 2019
(86) PCT No.: PCT/JP2019/048402

§ 371 Date: Jul. 31, 2020

(30) Foreign Application Priority Data
Mar. 12, 2019 (JP) 2019-044361

(51) Int. Cl. C23C 14/54; H01L 21/66; C23C 14/34

(52) U.S. Cl. CPC C23C 14/545; C23C 14/34; H01L 22/26

(57) ABSTRACT

A method of forming a film of this invention includes: rotating, inside a vacuum chamber, a to-be-processed substrate with a center of the to-be-processed substrate, while revolving the to-be-processed substrate on the same plane about a revolution shaft; and feeding a film-forming material from a film-forming source to form a predetermined thin film on a surface of the to-be-processed substrate. Provided that a goal film thickness of the thin film to be formed be defined as T, and that a film thickness of the thin film to be formed on the to-be-processed substrate in one revolution period be defined as D, the method further includes a setting process for setting a ratio α of rotation angular velocity Ωrot to a revolution angular velocity Ωrev of the to-be-processed substrate to a value satisfying the following formula (1)

α≥6/log₁₀(T/D) (1)

### TECHNICAL FIELD

The present invention relates to a film forming method in which: while a subsrate to be processed (hereinafter called a “to-be-processed substrate”) is revolved on the same plane about a revolution shaft inside a vacuum chamber, the to-be-processed substrate is rotated with the center of the to-be-processed substrate serving as the center of turning; a film-forming material is fed from a film-forming source which is disposed inside the vacuum chamber at a predetermined position lying opposite to the to-be-processed substrate, whereby a predetermined thin film is formed on a surface of the to-be-processed substrate.

### BACKGROUND ART

As an apparatus capable of carrying out this kind of film forming method, the following sputtering apparatus is known, e.g., in the Patent Document 1. This apparatus is provided with a vacuum chamber which is capable of forming a vacuum atmosphere. Inside the vacuum chamber there is disposed a stage for holding the to-be-processed substrate. The stage is provided with a rotation shaft about the center of which is turned (rotated on its axis) the to-be-processed substrate, and a revolution shaft which is in parallel with the rotation shaft. It is thus so arranged that the stage can be turned about the revolution shaft (consequently revolving the to-be-processed substrate). Then, there is disposed a target as the film-forming source in that predetermined position inside the vacuum chamber which lies opposite to the rotated and revolved to-be-processed substrate. By sputtering this target, a predetermined thin film can be formed at a uniform film thickness distribution on the surface of the rotated and revolved to-be-processed substrate.

By the way, recently requirements are often made that the film be formed at a film thickness distribution below ±1% depending on the uses to which the thin film to be formed is put (e.g., optical thin film to be utilized in optical equipment or optical parts). The film thickness (called “goal film thickness”, “goal” meaning somemething that you hope to achieve) of the thin film on such an occasion covers in many cases a wide range of several tens of nanometers (nm) to several thousands of nm. In such a case, in order for the desired film thickness distribution to be obtained at a goal film thickness, most appropriate values of the revolution angular velocity and the rotation angular velocity of the to-be-processed substrate must appropriately be obtained. It will, however, take much time in the preliminary preparations for production if these most appropriate values must be obtained each time depending on the goal film thicknesses. Under the circumstances, it was desired to develop a method of easily setting appropriate values of the revolution angular velocity and the rotation angular velocity of the to-be-processed substrate depending on the goal film thicknesses.

### PRIOR ART DOCUMENTS

### Patent Documents

Patent Document 1:JP-A-2013-147677

### SUMMARY OF THE INVENTION

### Problems that the Invention is to Solve

In view of the above-mentioned points, this invention has a problem of providing a method of forming a film in which appropriate values of revolution angular velocity and rotation angular velocity of the to-be-processed substrate can be easily set depending on goal film thicknesses.

### Means for Solving the Problems

In order to solve the above-mentioned problem, this invention is a method of forming a film comprising: rotating, inside a vacuum chamber, a to-be-processed substrate with a center of the to-be-processed substratre serving as a center of turning, while revolving the to-be-processed substrate on a same plane about a revolution shaft; and feeding a film-forming material from a film-forming source to form a predetermined thin film on a surface of the to-be-processed substrate, the film-forming source being disposed at a predetermined position inside the vacuum chamber in a manner to lie opposite to the rotated and revolved to-be-processed substrate. Provided that a goal film thickness of the thin film to be formed be defined as T, and that a film thickness of the thin film to be formed on the to-be-processed substrate in one revolution period (cycle) be defined as D, the method further comprises a setting process for setting a ratio α of rotation angular velocity to a revolution angular velocity of the to-be-processed substrate to a value satisfying the following formula (1) (excluding a case amounting to an integral multiple and a half-integral multiple)

α≥6/log₁₀(T/D) (1)

Here, that number of revolution N of the to-be-processed substrate which is required for forming a film up to the desired film thickness can be calculated by dividing the goal film thickness T by the film thickness D of the thin film to be formed on the to-be-processed substrate in one revolution period. However, the inventors of this application paid attention to the relationship between this calculated number of revolution N (=T/D) and the ratio α (rotation to revolution ratio) of a rotation angular velocity to a revolution angular velocity of the to-be-processed substrate. As a result of strenuous efforts in studying, they have obtained a finding that the above-mentioned formula (1) is satisfied when a predetermined film thickness distribution (e.g., below ±1%) can be obtained over an entire surface of the substrate. Accordingly, if setting is made of the desired goal film thickness T and one of the revolution angular velocity (revolution number of the substrate) and the rotation angular velocity (rotation number of the substrate), e.g., based on the apparatus specification, setting can be easily made, from the above-mentioned formula (1), of the other of the revolution angular velocity (revolution number of the substrate) and the rotation angular velocity (rotation number of the substrate). In this manner, according to this invention, if setting is made of an optimal value of the revolution angular velocity or the rotation angular velocity of the substrate depending on the goal film thickness, a predetermined thin film of a predetermined film thickness distribution (e.g., below ±1%) can be formed over an entire surface of the substrate. By the way, in case the ratio α becomes an integral multiple and a half-integral multiple (inclusive of values in the neighborhood of the integral multiple and the half-integral multiple, depending on the film thickness distribution intended to be obtained), only partial regions of the rotated and revolved substrate come to cross the regions lying opposite to the target, resulting in the presence of the regions in which the film thickness becomes locally larger. As a solution, an integral multiple and a half-integral multiple may be removed so that the film thickness distribution does not deteriorate.

By the way, in case a target is used as the film-forming source, a sputtering gas is introduced into the vacuum chamber and, at the same time, the target is charged with electric power, thereby sputtering the target so that the sputtered particles scattered from the target are caused to be adhered to, and deposited on, the surface of the to-be-processed substrate to thereby form a film, there are cases where plasma discharge becomes unstable (for example, abnormal electric discharge is induced) if the above-mentioned ratio α becomes larger beyond the predetermined value. Then, as a result of strenuous efforts in studying by the inventors of this application, they have found that, when the maximum velocity Vs [m/s] of the rotated and revolved to-be-processed substrate becomes larger than the root-mean-square velocity Vg of the sputtering gas, the plasma discharge is likely to become unstable. Therefore, in this invention, provided that a radius of the to-be-processed substrate be defined as Rr, a revolution radius of the to-be-processed substrate be Rs, a revolution angular velocity of the to-be-processed substrate be Ωrev, a rotation angular velocity of the to-be-processed substrate be Ωrot, and a maximum velocity of the to-be-processed substrate to be obtained by (Rs+Rr)×(Ωrev+Ωrot) be Vs, the method further comprising the step of setting, in the setting process, the ratio α to a value further satisfying the following formula (2)

α<(1/Ωrev)×(Vg/(Rs+Rr))−1 (2)

### BRIEF DESCRIPTION OF THE DRAWINGS

FIG. 1 is a schematic sectional view showing a sputtering apparatus which performs the method of forming a film according to an embodiment of this invention.

FIG. 2 is a schematic plan view of the sputtering apparatus shown in FIG. 1.

FIGS. 3(a) to FIGS. 3(c) are graphs respectively showing experiment results of this invention.

FIG. 4 is a graph showing a range of ratio α of rotation angular velocity to a revolution angular velocity, as obtained by the experiments of this invention.

### MODES FOR CARRYING OUT THE INVENTION

With reference to the drawings, a description will now be made of an embodiment of a film forming method of this invention in which a glass substrate or a silicon wafer (hereinafter called “substrate Sw”) is employed as the to-be-processed substrate and in which a thin film of a predetermined thickness is formed on the surface of the substrate Sw by a sputtering method.

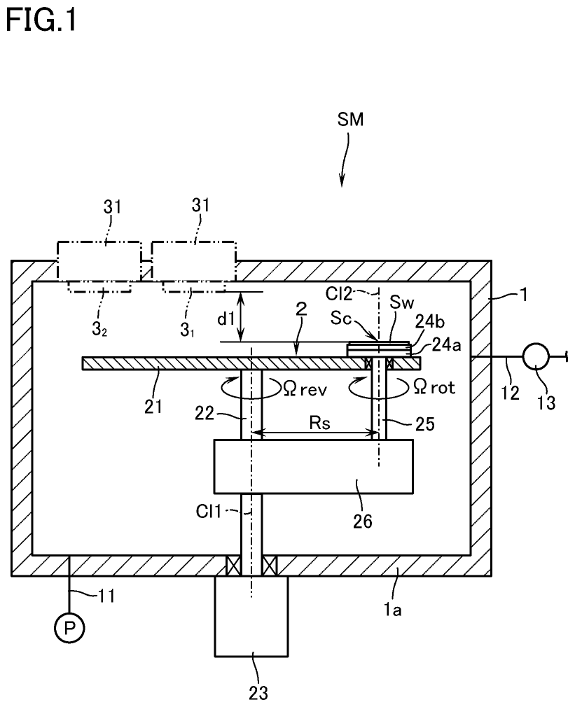

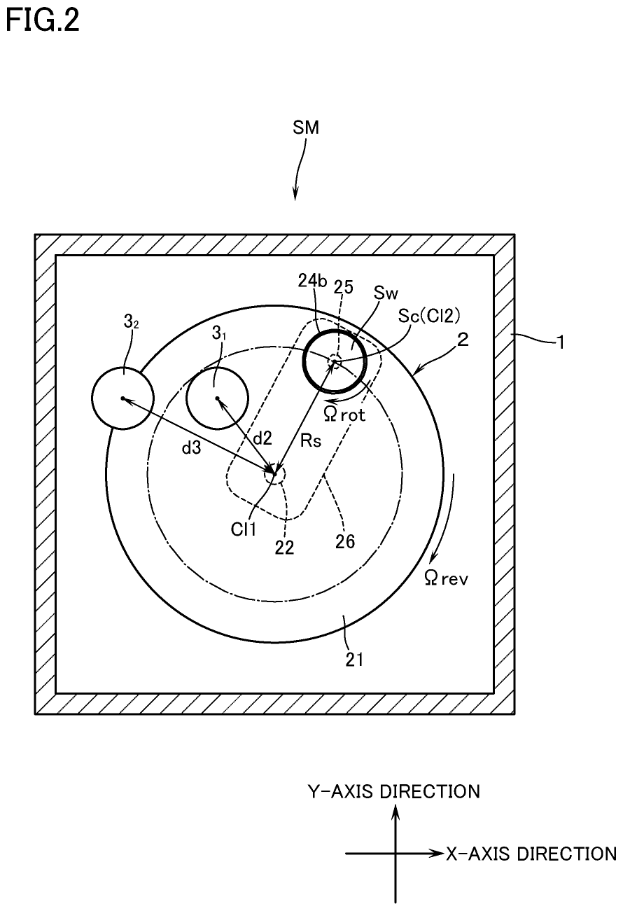

With reference to FIG. 1 and FIG. 2, reference mark SM denotes a sputtering apparatus that is capable of performing the film forming method of this invention. The sputtering apparatus SM is provided with a vacuum chamber 1. In the following description, the terms to designate the directions such as “upper”, “lower” and the like are based on FIG. 1 which shows the posture of installation of the sputtering apparatus SM.

Although not particularly explained by illustration, the vacuum chamber 1 has connected thereto an exhaust pipe 11 from a vacuum pump unit P which is constituted by a turbo-molecular pump or a rotary pump. It is thus so arranged that the inside of the vacuum chamber 1 can be evacuated down to a predetermined pressure. The vacuum chamber 1 has connected thereto a gas introduction pipe 12 for introducing a sputtering gas into the inside of the vacuum chamber 1. The gas introduction pipe 12 is in communication with a gas source (not illustrated) through a mass flow controller 13. As the sputtering gas, aside from a rare gas such as argon gas and the like, a reactive gas such as oxygen gas, water vapor gas and the like are included in case a reactive spttering is performed. It is so arranged that, after having evacuated the inside of the the vacuum chamber 1 to a predetermined pressure, the sputtering gas that is controlled in flow amount by the mass flow controller 13 can be introduced into the vacuum chamber 1.

Inside the vacuum chamber 1 there is disposed a stage 2 which causes the substrate Sw to rotate and revolve. The stage 2 has a circular turn table 21 as seen in plan view. The turn table 21 has connected threreto a revolution shaft 22 which penetrates through a lower wall la of the vacuum chamber 1 and protrudes into the inside thereof. It is thus so arranged that, by turning to drive the revolution shaft 22 by a motor 23 disposed outside the vacuum chamber 1, the turn table 21 can be turned, and consequently the substrate Sw can be turned (revolved), about an axial line Cl1 that passes through the center of the turn table 21. Further, on the turn table 21 there is a chuck plate 24b which is disposed on a plate-like base 24a made of metal and which has a profile equivalent to that of the substrate Sw. Although not particularly explained by illustration, the chuck plate 24b has buried therein electrodes for an electrostatic chuck. It is so arranged that, by supplying electric power to the electrodes, e.g., in a contact-free manner, from an electric power source for the electrostatic chuck, the substrate Sw can be electrostatically sucked to the upper surface of the chuck plate 24b. The base 24a has connected thereto a rotation shaft 25 that penetrates through the turn table 21 in the direction of the plate thickness. It is thus so arranged that, by turning to drive the rotation shaft 25 about an axial line Cl2 that passes through the center of the chuck plate 24b, the base 24a and the chuck plate 24b, and consequently the substrate Sw can be turned (rotated) with the substrate center Sc serving as the center of turning. In this case, the rotation shaft 25 is connected to the revolution shaft 22, e.g., through a continuously variable transmission 26 having a known construction such as belt type, chain type and the like. When the revolution shaft 22 is driven for turning by the motor 23, the rotation shaft 25 is arranged to be turned for driving at an arbitrary angular velocity. In other words, a ratio (hereinafter also called “rotation to revolution ratio”) α of the rotation angular velocity Ωrot to the revolution angular velocity Ωrev of the substrate Sw can be changed.

At an upper part of the vacuum chamber 1, there is disposed at least one of the targets 3 as a film-forming source in a manner to lie opposite to the substrate Sw. In this embodiment, provided that two directions crossing each other at right angles on the same plane be respectively defined as an X-axis direction and a Y-axis direction, two targets 3₁, 3₂, each having a profile equivalent to, and having an area smaller than, that of the substrate Sw, are disposed in parallel with, and at a distance from, each other in the X-axis direction. As the targets 3₁, 3₂, there may be used ones having the equivalent profile as that of the substrate Sw, and made of a metal or an electrically insulating material selected depending on the composition of the thin film to be formed on the surface of the substrate Sw. The distance (T/S distance) d1 in the vertical direction from the substrate Sw to the targets 3₁, 3₂ is set to a range, e.g., of 150 to 250 mm. By the way, those surfaces (upper surfaces) of the targets 3₁, 3₂ which lie opposite to the sputtering surfaces (i.e., the surfaces to get sputtered) have adhered thereto backing plates 31. It is thus so arranged that, at the time of sputtering the targets 3₁, 3₂, a coolant is circulated through the backing plates 31 so as to cool the targets 3₁, 3₂. The targets 3₁, 3₂ have connected thereto an output from a sputtering power source such as a DC power source or an AC power source (both not illustrated) so that the DC power having a negative electric potential or the AC power of a predetermined frequency can be charged to the targets 3₁, 3₂ depending on the species of targets. Although not particularly illustrated, the above-mentioned sputtering apparatus SM has a known control means equipped with a micro computer, a sequensor and the like and, by this control means, an overall control is made over the operation of the vacuum pump unit P, the operation of the mass-flow controller 13, the operation of the sputterin power source, and the like. Although the details will be described hereinafter, the control means controls the operations of the motor 23 and the continuously variable transmission 26 so as to attain the revolution angular velocity Ωrev and the rotation angular velocity Ωrot that are set depending on the goal film thickness T of the thin film. A description will hereinafter be made of a method of forming a film on the surface of the substrate Sw according to this embodiment based on an example in which the above-mentioned sputtering apartratus SM is used.

After the chuck plate 24b of the stage 2 has electrostatically sucked the substrate Sw, argon gas as the sputtering gas is introduced into the vacuum chamber 1 that has been evacuated to a predetermined pressure, in a predetermined flow amount (the pressure inside the vacuum chamber 1 at this time is 1.5 Pa). When the electric power is charged from the sputtering power source to the targets 3₁, 3₂, plasma will be generated between the targets 3₁, 3₂ and the substrate Sw. The targets 3₁, 3₂ will then be sputtered by the ions of the sputtering gas ionized by the plasma. The sputtered particles scattered from the targets 3₁, 3₂ by sputtering will get adhered to, and deposited on, the surface of the substrate Sw, thereby forming a thin film. During film formation, by driving the motor 23 and the continuously variable transmission 26, the substrate Sw will be rotated and revolved. Here, that number of revolution N of the substrate Sw which is required for forming a film at a desired film thickness is calculated in advance by dividing the goal film thickness T by the film thickness D of the thin film to be formed on the substrate Sw in one revolution period. Once the calculated number of revolution N has reached, the introduction of the sputtering gas and the charging of the electric power to the targets 3₁, 3₂ are stopped, thereby finishing the film formation.

Here, as a preliminary preparation for film formation (production), optimum values of the revolution angular velocity Ωrev and the rotation angular velocity Ωrot of the substrate Sw will have to be obtained appropriately so that the desired film thickness distribution (e.g., below ±1%) can be obtained. However, as described above, the goal film thicknesses T of the thin films often extend a wide range. Therefore, it will take a vast amount of time if the optimum values must be obtained each time depending on the goal film thicknesses T.

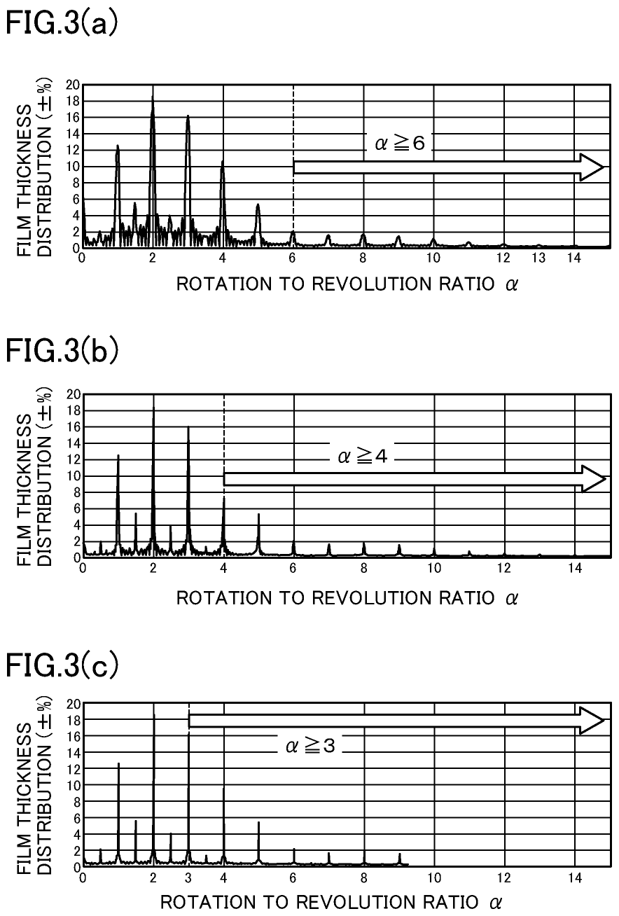

Then, the inventors of this invention carried out the following experiments using the above-mentioned sputtering apparatus SM. In Experiment 1, the substrate Sw was made of silicon wafer of 300 mmΦ (in diameter), the targets 3₁, 3₂ were made of silicon of 290 mmΦ, the distance (T/S distance) d1 from the substrate Sw to the targets 3₁, 3₂ was set to 250 mm, the center distances d2, d3 from the revolution shaft 22 to the targets 3₁, 3₂ were set to 450 mm, 800 mm, respectively, and the radius Rs of revolution of the substrate Sw was set to 600 mm (0.6 m), thereby forming silicon films on the following film-forming conditions. Namely, the flow rate of the argon gas as the sputtering gas was made to be 90 sccm (the pressure inside the vacuum chamber 1 at this time was 1.5 Pa), and the DC electric power to be charged to the targets 3₁, 3₂ was set to be 3 kW and 9 kW, respectively. The thickness D of the thin film to be formed on the substrate Sw in one revolution period under the above-mentioned film-forming conditions was 0.35 nm/revolution. For this reason, in this Experiment 1 if the goal film thickness T was set to 3.5 nm, the number of revolution N (=T/D) required for the film formation was calculated to be 10 turns. The results of having obtained the film thickness distribution (the in-plane film thickness measurement points of the substrate Sw were 49 points) by varying the rotation to revolution ratio α are given in FIG. 3(a). As shown in FIG. 3(a), it has been confirmed that the film thickness distribution can be kept below ±1% if the rotation to revolution ratio α was set above 6, excluding a case in which the rotation to revolution ratio α becomes an integral multiple and a half-integral multiple as well as a case in which the ratio α becomes a value in the neighborhood thereof at which the film thickness distribution becomes deteriorated (a case in which the formula |α−round (α/0.5)×0.5|≤0.05 is satisfied, where round (A) is a processing of rounding off A into an integer. The same applies to the Experiment 2 and Experiment 3 to be described hereinafter).

Next, in Experiment 2, except for the points that the goal film thickness T was set to 10 nm and that the number of revolution N (=T/D) required for the film formation was calculated to be 30 turns, in the same manner as in the above Experiment 1, the rotation to revolution ratio α was varied to obtain the film thickness distribution. The results are shown in FIG. 3(b). According to the results, it has been confirmed that the film thickness distribution was able to be kept below ±1% if the rotation to revolution ratio α was set above 4, excluding a case in which the rotation to revolution ratio α becomes an integral multiple and a half-integral multiple as well as a case in which the ratio α becomes a value in the neighborhood thereof (a case in which the formula |α−round (α/0.5)×0.5|≤0.05 is satisfied).

Next, in Experiment 3, except for the points that the goal film thickness T was set to 31.5 nm and that the number of revolution N (=T/D) required for the film formation was calculated to be 90 turns, the film thickness distribution was obtained by varying the rotation to revolution ratio α in a manner similar to the above-mentioned Experiment 1. The results are shown in FIG. 3(c). According to the results, it has been confirmed that the film thickness distribution was able to be kept below ±1% if the rotation to revolution ratio α was set above 3, excluding a case in which the rotation to revolution ratio α becomes an integral multiple and a half-integral multiple as well as a value in the neighborhood thereof (a case in which the formula |α−round (α/0.5)×0.5|≤0.05 is satisfied).

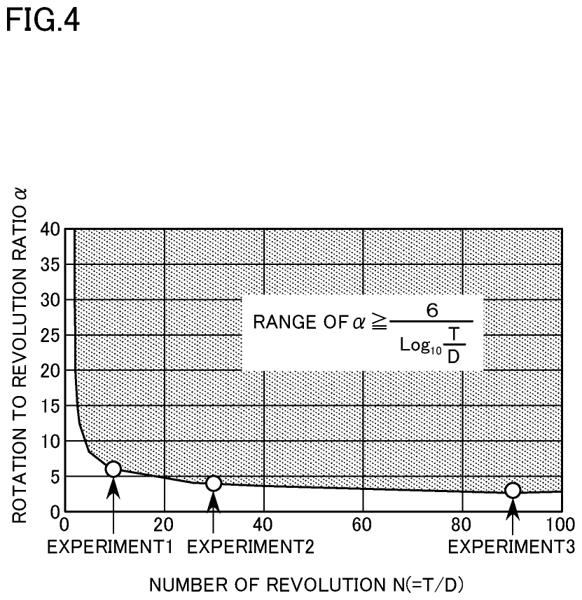

According to the above-mentioned Experiments 1 to 3, it has been confirmed that, when a predetermined film thickness distribution (below ±1%) can be obtained over an entire surface of the substrate Sw, the following formula (1) was satisfied as shown in FIG. 4 (excluding a case in which the rotation to revolution ratio α becomes an integral multiple and a half-integral multiple as well as a case in which the ratio α becomes a value in the neighborhood thereof (a case in which the formula |α−round (α/0.5)×0.5|≤0.05 is satisfied)

α≥6/log₁₀(T/D) (1)

According to the above, if setting is made of the desired goal film thickness T, and one of the revolution angular velocity Ωrev (number of revolution of the substrate Sw) or the rotation angular velocity Ωrot (number of rotation of the substrate Sw) e.g., from the specification of the sputtering apparatus SM, the other of the revolution angular velocity Ωrev (number of revolution of the substrate Sw) or the rotation angular velocity Ωrot (number of rotation of the substrate Sw) can be easily set from the above-mentioned formula (1) (setting step). In this manner, according to this embodiment, by setting the most appropriate value of the revolution angular velocity Ωrev and the rotation angular velocity Ωrot of the substrate Sw depending on the goal film thickness T, a predetermined thin film of a predetermined film thickness distribution (e.g., below 35 1%) can be formed over an entire surface of the substrate Sw. By the way, in case the rotation to revolution ratio α becomes an integral multiple and a half-integral multiple (inclusive of values in the neighbourhood of the integral multiple and the half-integral multiple depending on the film thickness distribution that is going to be obtained), the rotated and revolved substrate Sw will only partly cross the regions that lie opposite to the targets 3₁, 3₂. As a result, regions in which the film thicknesses get locally larger are likely to occur, whereby the film thickness distribution becomes deteriorated. Therefore, such case (the integral multiple and the half-integral multiple) shall preferably be removed.

By the way, when the above-mentioned rotation to revolution ratio α becomes larger beyond a predetermined value, there are cases where plasma discharge becomes unstable (for example, abnormal discharge will be induced). As a result of strenuous efforts of studying, the inventors of this application have obtained a finidng that plasma discharge is likely to get unstable if the maximum velocity Vs [m/s] of the rotated and revolved substrate Sw becomes larger than the root-mean-square velocity Vg of the sputtering gas. Therefore, in this embodiment, it is preferable to set the ratio α, in the above-mentioned setting step, to a value that further satisfies the following formula (2)

α<(1/Ωrev)×(Vg/(Rs+Rr))−1 (2)

where a radius of the substrate Sw is Rr, a revolution radius of the substrate is Rs, a revolution angular velocity of the substrate Sw is Ωrev, a rotation angular velocity of the substrate Sw is Ωrot, and a maximum velocity of the substrate Sw to be obtained by (Rs+Rr)×(Ωrev+Ωrot) is Vs.

In addition to the conditions of the above-mentioned Experiment 1, the revolution angular velocity Ωrev=100 rpm (=10.5 rad/s) and the root-mean-square velocity Vg=300 m/s are substituted into the above-mentioned formula (2), then α<37.2 is obtained. It has thus been confirmed that, if the rotation to revolution ratio α is set within this range, the plasma discharge can be prevented from getting unstable.

A description has so far been made of an embodiment of this invention, but various modifications can be made as long as the technical idea of this invention is not deviated. The above description was made of an example of forming a film by a sputtering method, but this invention may also be applicable to film forming by a vacuum deposition method. In this case, as the film-forming source, there may be used a crucible for containing therein a deposition material such as an organic material, and a heating means for heating this crucible. The crucible containing therein the organic material is heated by the heating means, and the evaporated or vaporized organic material is caused to get adhered from the crucible to the surface of the substrate, thereby forming a thin film thereon.

In addition, in the abovementioned embodiment, description was made of an example in which two targets 3₁, 3₂ were disposed in parallel with each other at a distance therebetween. Alternatively, only one target 3 having a larger area than the substrate Sw may be disposed. In addition, in the above-mentioned embodiment, a continuously variable transmission 26 was used in turning to drive the rotation shaft 25 at an arbitrary rotation angular velocity Ωrot. It may alternatively be so arranged that a motor other than the motor 23 to turn the revolution shaft 22 is used so that the rotation shaft 25 is turned for driving at an arbitraty rotation angular velocity Ωrot.

### EXPLANATION OF MARKS

α. . . rotation to revolution ratio (ratio of rotation angular velocity to revolution angular velocity of a substrate)
D . . . film thickness of a thin film to be formed on a substrate at one revolution period
Rr . . . radius of substrate
Rs . . . radius of revolution of substrate
Ωrev . . . revolution angular velocity of substrate
Ωrot . . . rotation angular velocity of substrate
SM . . . sputtering apparatus
Sw . . . substrate (to-be-processed substrate)
T . . . goal film thickness of thin film to be formed
1 . . . vacuum chamber
22 . . . revolution shaft
3₁, 3₂ . . . targets (film-forming source)

1. A method of forming a film comprising:
rotating, inside a vacuum chamber, a to-be-processed substrate with a center of the to-be-processed substratre serving as a center of turning, while revolving the to-be-processed substrate on a same plane about a revolution shaft;
feeding a film-forming material from a film-forming source to form a predetermined thin film on a surface of the to-be-processed substrate, the film-forming source being disposed at a predetermined position inside the vacuum chamber in a manner to lie opposite to the rotated and revolved to-be-processed substrate;
provided that a goal film thickness of the thin film to be formed be defined as T, and that a film thickness of the thin film to be formed on the to-be-processed substrate in one revolution period be defined as D, the method further comprising a setting process for setting a ratio α of rotation angular velocity to a revolution angular velocity of the to-be-processed substrate to a value satisfying the following formula (1) (excluding a case amounting to an integral multiple and a half-integral multiple)
α≥6/log₁₀(T/D) (1).

2. The method of forming a film according to claim 1, further comprising: using a target as the film-forming source, introducing a sputtering gas into the vacuum chamber, and charging the target with electric power so that sputtered particles scattered from the target are caused to be adhered to, and deposited on, the surface of the to-be-processed substrate to thereby form the film;
provided that a radius of the to-be-processed substrate be defined as Rr, a revolution radius of the to-be-processed substrate be Rs, a revolution angular velocity of the to-be-processed substrate be Ωrev, a rotation angular velocity of the to-be-processed substrate be Ωrot, and a maximum velocity of the to-be-processed substrate to be obtained by (Rs+Rr)×(Ωrev+Ωrot) be Vs, the method further comprising the step of setting, in the setting process, the ratio α to a value further satisfying the following formula (2)
α<(1/Ωrev)×(Vg/(Rs+Rr))−1 (2)
